(19) United States
(12) Patent Application Publication
(10) Pub. No.: US 2006/0203559 A1
(43) Pub. Date: Sep. 14, 2006

(54) Memory device with customizable configuration

(76) Inventor: Peter Poechmueller, Dresden (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/067,914

(22) Filed: Feb. 28, 2005

(51) Int. Cl. G11C 11/34

(52) U.S. Cl. 365/185.22

(57) ABSTRACT

One embodiment of the present invention relates to a memory device in a package comprising a plurality of data output ports, a plurality of internal data lines for providing data to and from a memory unit, a switching unit which is operable, depending on an operational mode, either to connect a first number of the internal data lines to a first number of the plurality of data output ports in a first operational mode or to connect a second number of the internal data lines to a second number of the plurality data output ports in a second operational mode, wherein the first number is smaller than the second number; and a mode selector unit which is connected to the switching unit to set the operational mode of the switching unit, wherein the mode selector unit includes a programmable storage unit for writing mode data from externally and wherein the operational mode is determined depending on the mode data.

### BACKGROUND OF THE INVENTION

1. Field of the Invention

The present invention relates to memory devices having a preset configuration with respect to the number of operable data output ports.

2. Description of the Related Art

Memory devices such as dynamic random access memories (DRAMs) are sold in different quality grades, e.g., a high quality grade and a low quality grade. High quality memory devices are delivered to key customers and low quality memory devices are delivered to secondary markets and are often used for standard PC applications.

Moreover, memory devices such as DRAMs are offered in different I/O configurations, i.e., with a different number of data input and output ports. Most memory devices therefore have one of an ×4, ×8 or ×16 configuration, describing the number of data input/output ports. An ×4 organization, which means the memory device has only four data input/output ports, is typically used for server units as they require extremely high memory densities which are best achieved by the ×4 memory device configuration.

Usually, the layout of a memory device is fixed and the organization (e.g., ×4, ×8 or ×16 configuration) is typically defined by one of the last memory manufacturing steps (e.g., by providing a metal option, a laser fusing option or a bond option) before the final packaging. After the packaging, the set configuration is fixed and cannot be changed.

Particularly for memory devices with an ×4 configuration which are classified in a low quality grade, an issue exists since there is no need in the market for such low quality grade memory devices of such configuration. Because server units require server applications memory devices with high quality grades, low quality memory devices with an ×4 configuration cannot be utilized in such applications. As there is no other application for memory devices with ×4 configuration, such memory devices with a low quality grade are practically unmarketable.

Therefore, there is a need for a method to adapt memory devices according to market needs even after the memory devices have been packaged.

### SUMMARY OF THE INVENTION

One aspect of the present invention provides a memory device which can be adapted even after packaging to meet the market needs with respect to its configuration and/or quality classification.

According to one embodiment of the present invention, a memory device is provided comprising a plurality of data output ports, a plurality of internal data lines, a switching unit which is operable, depending on an operational mode, either to connect a first number of the internal data lines to a first number of the plurality of data output ports in a first operational mode or to connect a second number of the internal data lines to a second number of the plurality of data output ports in a second operational mode, wherein the first number is different from the second number (e.g. smaller); and a mode selector unit which is connected to the switching unit to set the operational mode of the switching unit, wherein the mode selector unit includes a programmable storage unit for writing mode data after packaging and wherein the operational mode is determined depending on the mode data.

The memory device according to one embodiment of the present invention has the advantage, that it comprises a storage unit which can be programmed from outside of the memory device and allows for the changing of the configuration of the memory device after packaging with respect to the number of data input/output ports the memory device is operated with. This allows for the adapting of the memory device to the actual market needs if the I/O configuration-quality grade combination is actually not marketable. Since many memory devices have the same package and package bonding for several configurations (e.g., an ×4 and ×8 configuration of a memory device are identical in package and bonding), the present invention provides the possibility of reconfiguring an ×4 memory device into an ×8 memory device by means of a storage unit which is externally programmable even after packaging.

The programmable storage unit may comprise an electrical fuse element which is electrically programmable and which is adapted to store either a first mode data or a second mode data. The electrical programming may be performed by applying programming voltages and currents to respective ports of the memory device.

The programmable storage unit may comprise a configuration setting unit which is settable before packaging and which is adapted to provide either a first mode data or a second mode data.

In one embodiment, the fixed mode setting unit includes at least one of a laser fuse element, a bond option structure and a metal option structure in the memory device layout.

According to one embodiment of the present invention, the configuration setting unit and the electrical fuse element are coupled to a logic circuit which is adapted to generate an operational mode signal indicating the operational mode, wherein the operational mode signal determines the first operational mode if the configuration setting unit has stored the first mode data and the electric fuse element has stored the first mode data, and wherein the operational mode signal determines the second operational mode if the configuration setting unit or the electrical fuse element has stored the second mode data.

In one embodiment, the data output ports of the first number of data output ports are comprised in (or comprise a portion of) the data output ports of the second number of data output ports.

In one embodiment, the first number of data output ports equals 4, and the second number of data output ports equals 8.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a top sectional view of a memory device showing an opened standard TSOP package and the bonding of an integrated memory circuit chip to respective output pins of the package;

FIG. 1B is a cross sectional view of the memory device taken along the line A-A;

FIG. 2 illustrates a part of the integrated memory circuit chip which shows the interconnection of the internal data lines to the data outputs of the memory circuit chip according to an embodiment of the present invention; and

FIG. 3 is a schematic diagram illustrating an embodiment of a mode selector unit for providing the operational mode.

### DETAILED DESCRIPTION OF THE PREFERRED EMBODIMENT

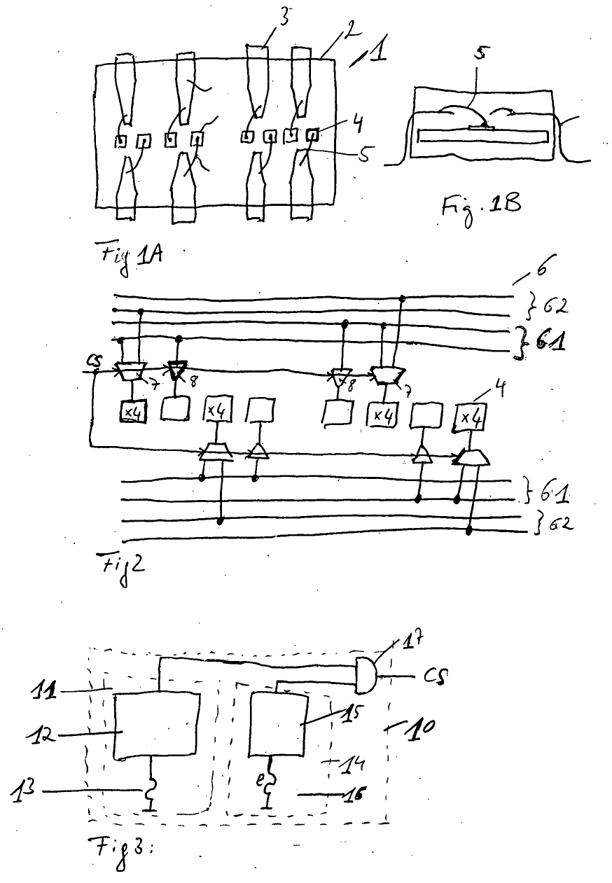

FIG. 1A shows a top sectional view of a memory device. FIG. 1B is a cross sectional view of the memory device taken along the line A-A. Referring to both FIGS. 1A and 1B, the memory device comprises an integrated memory circuit chip 1 and a TSOP package 2 which has data input/output pins 3 of a lead frame to provide data input/output ports which are externally accessible. The data input/output pins 3 are connected to contact pads 4 of the memory circuit chip 1. In one embodiment, the data input/output pins 3 are connected to the data contact pads 4 via bonding wires 5. The bonding wires 5 are applied in a bonding process wherein the data input/output pins 3 and the data contact pads 4 are interconnected to each other. In the illustrated example, the memory circuit chip 1 comprises eight data contact pads 4 which may be utilized for input/output (I/O) data communication. Further contact pads and further pins for other signals which are provided in the memory circuit chip 1 are not shown for the ease of illustration.

Embodiments of the present invention are not only related to this package type but describe a general approach which can be applied to all types of memory device packages, such as TSOP (Thin Small Outline Package), FBGA (Fine Pitch Ball Grid Array), TFBGA (Thin Fine Pitch Ball Grid Array), etc.

The bonding scheme shown in FIG. 1A, wherein each of the eight contact pads 4 is respectively connected to one of the data input/output pins 3, is valid for both an ×4 configuration memory device as well as for a ×8 configuration memory device. However, for a memory device with an ×4 configuration, only half of the data input/output ports are actively used. Thus, before packaging the memory circuit chip 1, it is decided whether an ×4 configuration memory device or an ×8 configuration memory device should be manufactured.

After the packaging of the memory circuit chip 1 into the package 2 to obtain a memory device, a classification is performed. The packaged memory devices are divided up into at least a high quality grade and a low quality grade according to the classification step. Depending on the configuration of the memory device, there may be less or more need for memory devices of a specific quality grade in the market. As the quality grade of the memory device cannot be influenced after the final packaging, the number of high or low quality grades of a memory device of a specific configuration type is not known in advance prior to the classification step. Therefore, with conventional memory devices, responding to market requirements is not possible.

In FIG. 2, a part of the memory chip circuitry is illustrated which refers to the data contact pads 4. As part of the memory chip circuitry, internal data lines 6 are shown. Eight data lines are provided (e.g., on both sides of a line of the contact pads 4 which in the shown embodiment are arranged in the middle of the memory circuit chip 1). The contact pads 4 are each connected with one or more data lines via a respective switching device (e.g., multiplexer, controllable driver, etc.) 7, 8, wherein the contact pads 4 which are used in a memory device with an ×4 configuration are each connected with two of the data lines 6 via a multiplexer 7 and the contact pads 4 which are only used by the memory device with the ×8 configuration are connected each via a controllable driver 8 with one of the data lines 6.

Each of the drivers 8 and each of the multiplexers 7 are controlled by the same control signal CS which defines the configuration of the data input/output ports of the memory device. The control signal determines whether the memory device is configured as an ×4 configuration memory device or an ×8 configuration memory device.

For example, with the control signal CS at a Low-level, the multiplexers 7 connect one of a first group 61 of the internal data lines with the respective data contact pad 4, respectively, and the drivers 8 are switched off to disconnect the remaining contact pads from the internal data lines. With the control signal CS at a High-level, the respective drivers 8 are switched on so that they connect one of the first group 61 of the internal data lines to the respective data contact pad 4, and the multiplexers 4 are switched so that they connect one of a second group 62 of the internal data lines, e.g., the respective data line pair which is more distanced from the contact pad line than the first group 61 of the internal data lines. Thus, if the control signal CS is at a Low-level, only four of the data contact pads 4 are connected to the respective internal data lines, and if the control signal CS is at a High-level, all eight internal data lines 6 are connected to their respective contact pads 4.

In conventional memory devices, the control signal CS is either hardwired set to a fixed potential, set by programming a laser fuse by means of a laser cutting process or set by an additional bond pad, resulting in that the control signal may not be set after packaging. According to one embodiment of the present invention, a mode selector unit 10 is provided on the memory circuit chip 1 which generates the control signal CS.

FIG. 3 is a schematic diagram illustrating an embodiment of a mode selector unit for providing the operational mode. The mode selector unit 10 comprises a laser fuse element 11 including a laser fuse latch 12 and a laser fuse 13. The laser fuse element 11 serves to preset the configuration type of the memory device to be produced. This is performed by cutting or not cutting the laser fuse 13 by means of the laser cutting process. After packaging, the laser fuse 13 is not accessible for a laser cutting process so that the configuration cannot be changed by re-programming the laser fuse element 11. According to one embodiment of the present invention, the mode selector unit 10 further comprises an electrical-fuse element 14 which includes an electrical fuse latch 15 and an electrical fuse 16. The electrical fuse 16 can be programmed by applying a programming voltage to the electrical fuse 16 by means of a respective programming circuit (not shown) or by applying the respective programming voltages to dedicated pins (not shown) of the memory device. Programming the electrical fuse 16 means that the electrical fuse is set to provide a high or low resistance depending on the programming. The high or low resistance is interpreted as a logical state which is stored in the electrical fuse latch 15. Similar to the laser fuse element 11, in the electrical fuse element 14, a first mode data is indicated by a Low-level at the output of the electrical fuse element 14, and a second mode data is indicated by a High-level at the output of the electrical fuse element 14. An output of the laser fuse element 11 and an output of the electrical fuse element 14 are connected to respective inputs of an AND gate 17. An output of the AND gate 17 outputs the control signal CS.

In the laser fuse element 11, for example, first mode data are stored if an ×8 configuration is to be preset, and second mode data are stored if an ×4 configuration is to be preset. The first mode data is indicated as a Low-level at the output of the laser fuse element 11, and the second mode data is indicated by a High-level at the output of the laser fuse element 11. A first mode data stored in the electrical fuse latch 15 indicates that the configuration preset of the laser fuse element should be valid, and a second mode data stored in the electrical fuse latch 15 indicates that the settings in the laser fuse elements 11 should be overrun and that an ×8 configuration should be set.

The laser fuse element 11 and the electrical fuse element 14 have permanently stored data. During chip power-up, the information in the laser fuse 13 and the information of the electrical fuse 16 is read out and stored in the respective fuse latch 12, 15.

Implementation of embodiments of the present invention is not restricted to the mode selector unit according to this embodiment of the present invention. The mode selector unit may be implemented in a variety of other possible circuit designs. Furthermore, the present invention is not restricted to memory devices with a configuration of ×4 and ×8. Configuration types of ×16 and ×32 are possible, as well, wherein memory devices can be provided wherein switching may take place between configurations of ×8 and ×16, and ×16 and ×32, respectively. Instead of an electrical fuse element 14, other types of storage units may be utilized which are capable of permanently storing the mode data which indicates the respective configuration type.

The switching devices herein realized as multiplexers 7 and controllable drivers 8 may be replaced by other switching device which is capable of depending on the control signal CS to connect a first number of internal data lines to the respective first number of contact pads 4 or to connect a second number of the internal data lines to the respective second number of contact pads 4. The set of the first number of internal data lines may be a portion of the set of the second number of internal data lines, and the set of the first number of contact pads 4 may be a portion of the set of the second number of contact pads 4.

While the foregoing is directed to embodiments of the present invention, other and further embodiments of the invention may be devised without departing from the basic scope thereof, and the scope thereof is determined by the claims that follow.

What is claimed is:

1. A packaged memory device, comprising:
a plurality of data input/output (I/O) ports;
a plurality of internal data lines for providing data to and from a memory unit;
a switching unit, which is operable depending on an operational mode, to connect the plurality of the internal data lines selectively to a first group of the plurality of data I/O ports in a first operational mode and to a second group of the plurality data I/O ports in a second operational mode, wherein the first group and the second group have different numbers of data I/O ports; and
a mode selector unit connected to the switching unit to set the operational mode of the switching unit, wherein the mode selector unit includes a programmable storage unit for writing mode data, wherein the operational mode is determined depending on the mode data.

2. The packaged memory device of claim 1, wherein the programmable storage unit comprises an electrical fuse element which is electrically programmable and adapted to store one of a first mode data and a second mode data.

3. The packaged memory device of claim 2, wherein the mode selector unit further comprises a configuration setting unit which is set before packaging and which is adapted to provide one of the first mode data and the second mode data.

4. The packaged memory device of claim 3, wherein the configuration setting unit includes at least one of a laser fuse element, a bond option structure and a metal option structure.

5. The packaged memory device of claim 4, wherein the mode selector unit further comprises a logic circuit coupled to receive output signals from the configuration setting unit and the programmable storage unit, wherein the logic circuit is adapted to generate an operational mode signal indicating the operational mode.

6. The packaged memory device of claim 5, wherein the operational mode signal indicates the first operational mode when the configuration setting unit and the electric fuse element output the first mode data and indicates the second operational mode when at least one of the configuration setting unit and the electrical fuse element output the second mode data.

7. The packaged memory device of claim 1, wherein the first group of data I/O ports is a part of the second group of data I/O ports.

8. The packaged memory device of claim 1, wherein the first group of data I/O ports has less data I/O ports than the second group of data I/O ports.

9. The packaged memory device of claim 1, wherein the first group of data I/O ports has four data I/O ports and the second group of data I/O ports has eight data I/O ports.

10. A memory device, comprising:
a first plurality of data ports;
a second plurality of data ports;
a first plurality of internal data lines;
a second plurality of internal data lines;
a first plurality of switching elements connected to the first plurality of data ports and selectably connected to the first and second pluralities of data lines depending on a control signal;
a second plurality of switching elements connected to the second plurality of data ports and selectably connected to one of the first and second pluralities of data lines depending on the control signal; and
a mode selector unit connected to provide the control signal to the first and second pluralities of switching elements, wherein the mode selector unit comprises a programmable storage unit which is programmable after the memory device is packaged and wherein the control signal depends upon the programming of the programmable storage unit.

11. The memory device of claim 10, wherein the first plurality of switching elements comprises multiplexers and the second plurality of switching elements comprise controllable drivers.

12. The memory device of claim 10, wherein the control signal indicates one of a first operating mode and a second operating mode.

13. The memory device of claim 12, wherein, in the first operating mode, the first plurality of switching elements is switched to connect the first plurality of data ports to the first and second pluralities of data lines and the second plurality of switching elements is switched to disconnect the second plurality of data ports from the data lines.

14. The memory device of claim 13, wherein, in the second operating mode, the first plurality of switching elements is switched to connect the first plurality of data ports to the first plurality of data lines and the second plurality of switching elements is switched to connect the second plurality of data ports to the second plurality of data lines.

15. The memory device of claim 12, wherein the mode selector unit further comprises a configuration setting unit which is set before packaging and which is adapted to provide a default mode data indicating one of the first operational mode and the second operational mode.

16. The memory device of claim 15, wherein the mode selector unit further comprises a logic circuit coupled to receive output signals from the configuration setting unit and the programmable storage unit, wherein the logic circuit is adapted to generate the control signal indicating one of the first operational mode and the second operational mode.

17. A method for configuring a memory device, comprising:
programming the memory device to operate in a first mode of operation, wherein a first plurality of data ports are connected to a first and a second pluralities of data lines;
packaging the memory device in a housing; and
after packaging the memory device, programming the memory device to operate in a second mode of operation, wherein the first plurality of data ports are connected to the first plurality of data lines and the second plurality of data ports are connected to the second plurality of data lines.

18. The method of claim 17, wherein a mode selector unit is programmed to provide a control signal to the first plurality of switching elements connected to the first plurality of data ports and selectably connected, depending on the control signal, to the first and the second pluralities of data lines and to provide the control signal to a second plurality of switching elements connected to a second plurality of data ports and selectably connected, depending on the control signal, to one of the first and second pluralities of data lines.

19. The method of claim 18, wherein, in the first operating mode, the first plurality of switching elements is switched to connect the first plurality of data ports to the first and second pluralities of data lines and the second plurality of switching elements is switched to disconnect the second plurality of data ports from the data lines, and wherein, in the second operating mode, the first plurality of switching elements is switched to connect the first plurality of data ports to the first plurality of data lines and the second plurality of switching elements is switched to connect the second plurality of data ports to the second plurality of data lines.

20. The method of claim 19, wherein the first operating mode is programmed by setting a configuration setting unit which includes at least one of a laser fuse element, a bond option structure and a metal option structure, and wherein the second operating mode is programmed by setting an electrical fuse element which is electrically programmable.
